(19) United States
(12) Patent Application Publication
(10) Pub. No.: US 2015/0082887 A1
(43) Pub. Date: Mar. 26, 2015

(54) SENSOR ELEMENT WITH AN ACOUSTIC EMISSION SENSOR

(71) Applicants: Arno Haschke, Erlangen (DE); Hans-Henning Klos, Feucht (DE); Dirk Scheibner, Nurnberg (DE); Jürgen Schimmer, Nurnberg (DE); Ronald Weigel, Bayreuth (DE)

(72) Inventors: Arno Haschke, Erlangen (DE); Hans-Henning Klos, Feucht (DE); Dirk Scheibner, Nurnberg (DE); Jürgen Schimmer, Nurnberg (DE); Ronald Weigel, Bayreuth (DE)

(73) Assignee: SIEMENS AKTIENGESELLSCHAFT, Munich (DE)

(21) Appl. No.: 14/391,896

(22) PCT Filed: Apr. 12, 2012
(86) PCT No.: PCT/EP2012/056697

§ 371 Date: Nov. 19, 2014

(51) Int. Cl. G01N 29/14; G01M 13/04; G01R 33/02

(52) U.S. Cl. CPC G01N 29/14; G01R 33/02; G01M 13/045; G01N 2291/044
USPC 73/587

(57) ABSTRACT

A sensor element includes an acoustic emission sensor for detecting acoustic emission. The sensor element has a second sensor for a second measured variable which is different from acoustic emission. Furthermore, a sensor element is provided, which includes an acoustic emission sensor for detecting acoustic emission and includes an interface for receiving an external sensor signal.

### CROSS REFERENCE TO RELATED APPLICATIONS

This application is based on and hereby claims priority to International Application No. PCT/EP2012/056697 filed on Apr. 12, 2012, the contents of which are hereby incorporated by reference.

### BACKGROUND

The invention relates to a sensor element with an acoustic emission sensor for measuring acoustic emission.

The condition monitoring of industrial installations is becoming increasingly important. The term ‘Acoustic Emission’ is used below. This term has established itself in the technical domain as a precise designation of a technology with which structure-borne sound is measured which does not occur in the case of reversible material changes, but only in the case of irreversible material changes. An evaluation of structure-borne sound in the ultrasound range (acoustic emission) is recognized as a tool for identifying material defects and material fatigue processes. In a range of applications, acoustic emission provides characteristic signals enabling an inference to be made regarding the process to be monitored, for example for bearing monitoring, tool monitoring or corrosion detection. The acoustic emission signal alone does not often provide evidence which is sufficiently clear. For example, heating processes similarly generate an acoustic emission due to thermal expansion.

Sensors for measuring acoustic emission are typically manually produced piezo sensors with a broadband or resonant characteristic. Measuring systems are available for general laboratory applications or for special applications, such as tool monitoring on machine tools. These systems evaluate only the acoustic emission signal. The pure evaluation of the measured acoustic emission signals is susceptible to noise signals and misinterpretations. Following the transfer of the acoustic emission data from the acoustic emission sensor into a higher-order device, a correlation with other measured quantities can be carried out (for example by MATLAB on the PC). However, the devices required for this purpose are complex and costly, and are unsuitable for an integration into industrial environments.

### SUMMARY

One possible object is to provide a sensor element with an acoustic emission sensor with which the performance of measurement tasks is simplified. Furthermore, an potential object is to provide a monitoring system, in particular a corrosion monitoring system, a bearing monitoring system or a machine monitoring system with which the performance of measurement tasks is simplified.

The inventors propose that the sensor element with an acoustic emission sensor for measuring acoustic emission comprises a second sensor for a second measured quantity which is different from acoustic emission. As a result, a processed (refined) sensor output can be provided with only one sensor component and cost for a further component, wiring cost and/or cost for a subsequent processing of the raw measured values can be at least partially saved. Furthermore, a precise positioning of the second sensor in relation to a position of the acoustic emission sensor is thus reliably ensured.

The inventors also propose a sensor element with an acoustic emission sensor for measuring acoustic emission comprises an interface for picking up an external sensor signal.

The external sensor signal can be provided, for example, from a rotational speed sensor or a different sensor which cannot be integrated into the sensor element due to the remoteness of the measurement location or for structural reasons. A rotational speed measurement is often advantageous for the evaluation of condition monitoring sensors, since the diagnosis quality can be significantly improved by the additional evidence from a supplementary sensor. Furthermore, a rotational speed measurement by synchronization with periodic disturbance quantities enables an improved suppression of these disturbance quantities.

In terms of the monitoring system, the monitoring system comprises the proposed sensor element.

Embodiments provide that the second sensor is a temperature sensor for measuring a temperature level and/or a temperature gradient, or that the second sensor is an oscillation sensor for measuring an oscillation characteristic, or that the second sensor is a magnetic field sensor for measuring a magnetic field strength and/or a magnetic field direction. The oscillation sensor can also be referred to as a vibration sensor. The selection of the sensors can be adapted according to the monitoring task.

A 3D Hall-effect sensor, for example, can be used to measure the magnetic field strength and/or the magnetic field direction. The measurement of a magnetic fingerprint which is characteristic of a machine condition, is thus possible. Different evaluation strategies are conceivable: evaluation of an intrinsic magnetic field of the machine (for example on a motor) and/or a rotational speed determination from a magnetic field change of a rotating magnetic field of an electric motor or an electric generator. It is also possible to evaluate a modulation of a magnetic field (“DC magnetic field”), the direction of which remains constant, in order to determine a rotor position of a linear motor by evaluation of a shunt change on end stops or on the arresting of the rotor. If a 3D magnetic field sensor is used, the alignment of the sensor in relation to the magnetic field is uncritical, since the magnetic field vector can be evaluated.

Advantageous further developments of the sensor element comprise a third sensor for measuring a temperature level, a vibration characteristic and/or a magnetic field strength and/or a magnetic field direction.

Also under the first aspect, the sensor element can comprise an interface to pick up an external sensor signal. Advantages resulting therefrom have already been explained.

It is preferred if the sensor element comprises an evaluation device to generate a consolidated and/or condensed sensor signal by evaluation of a sensor signal of the acoustic emission sensor, taking into account the second measured quantity and/or the external sensor signal. The sensor can comprise one or more algorithms for signal fusion of the measured quantities. An algorithm of this type may comprise, for example, a simple threshold value monitoring or a correlation calculation between two measured quantities. The algorithms can be available as diagnosis blocks which can be separately or jointly activated and/or deactivated.

It is particularly preferred if a program code is loadable into the evaluation device and/or if a program code is executable in the evaluation device. Application-specific evaluation algorithms can thereby be loaded into the sensor element separately or combined with one another and optionally executed there. It can be provided that the program code can be loaded into the sensor element via a different interface or via the same interface as the program code.

It is similarly advantageous if the evaluation device is prepared in order to carry out a correlation between signals which are measurable by the first and the second sensor and/or by the first and the third sensor and/or by the first and the fourth sensor and/or by a pair of the second to the fourth sensors. The reliability of a condition characteristic value selected by the sensor element can thereby be increased.

Embodiments provide that the evaluation device is prepared in order to carry out a correlation between the external sensor signal and a sensor signal of the first and/or the second and/or the third and/or the fourth sensor. The reliability of a condition characteristic value selected by the sensor element can thereby also be increased.

### BRIEF DESCRIPTION OF THE DRAWINGS

These and other objects and advantages of the present invention will become more apparent and more readily appreciated from the following description of the preferred embodiments, taken in conjunction with the accompanying drawings of which:

FIG. 1 shows a schematic block diagram of a sensor element, and

FIG. 2 shows, not to scale, a variation with time in a plausibility characteristic value depending on different, similarly shown, temporarily variable measured quantities.

### DETAILED DESCRIPTION OF THE PREFERRED EMBODIMENT

Reference will now be made in detail to the preferred embodiments of the present invention, examples of which are illustrated in the accompanying drawings, wherein like reference numerals refer to like elements throughout.

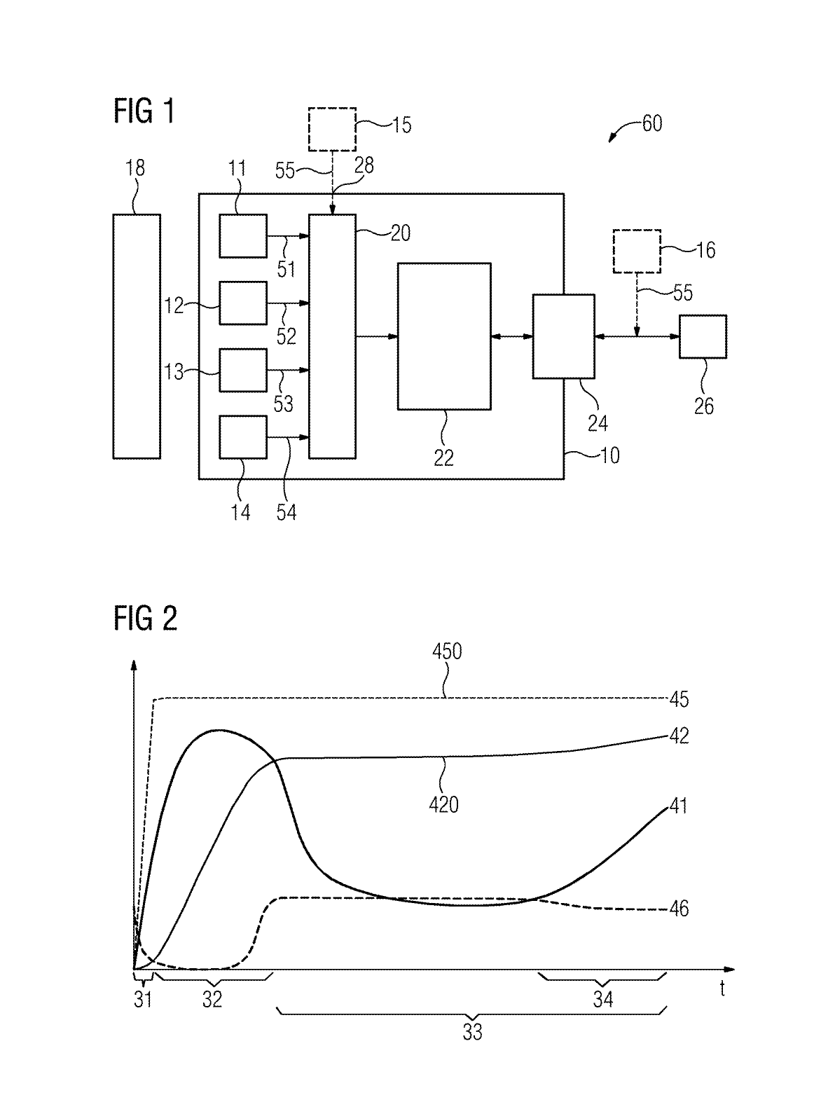

The monitoring system 60 shown in FIG. 1 for monitoring a monitoring object 18 comprises a higher-order monitoring device 26 and a sensor element 10 connected thereto. The sensor element 10 comprises a plurality of sensors 11, 12, 13, 14 for physically different measured quantities, a data acquisition circuit 20, an evaluation device 22 for acquired measured values 51, 52, 53, 54, 55 and an interface 24 for connecting the higher-order monitoring device 26.

The first sensor 11 is an acoustic emission sensor for generating electrical signals depending on a strength and/or direction of measured acoustic emission. The second sensor 12 is a temperature sensor for generating electrical signals depending on a measured temperature level and/or a strength and/or direction of a temperature gradient. The third sensor 13 is a vibration sensor for generating electrical signals depending on a strength, frequency and/or direction of measured vibrations. The fourth sensor 14 is a magnetic field sensor for generating electrical signals depending on a strength and/or direction of a measured magnetic field.

Optionally, the sensor element 10 also comprises an interface 28 for feeding signals 55 from one or more external sensors 15. Independently therefrom, signals 55 can also be fed from an external sensor 16 via the interface 24 which is provided for the connection of the sensor element 10 to the higher-order monitoring device 26. One embodiment appropriate for some applications provides that the interface 24, 28 for the external sensor 15, 16 is prepared in order to feed a rotational speed signal 55 from a rotational speed sensor 15, 16 and/or a bearing current signal 55 from a bearing current sensor 15, 16.

With reference to FIG. 2, it will now be explained, using the example of a bearing diagnosis, how a plausibility characteristic value 46, which is used as a measure of an applicability and/or validity of a measured acoustic emission activity 41, can be generated by the sensor element 10 from measured values 51, 52, 53, 54, 55 of a plurality of physically different measured quantities 41, 42, 45. In the example, it is assumed that the bearing 18 is operated in a normal operating phase 33 with a more or less constant normal operating rotational speed 450. At the beginning of the commissioning of the bearing 18, a run-up phase 31 initially takes place in which the rotational speed 42 is increased to the normal operating rotational speed 450. The run-up phase 31 is followed by a warm-up phase 32 in which, although the normal operating rotational speed 450 has already been reached, the bearing 18 is only gradually heated to a normal operating temperature 420. The commissioning phase therefore comprises a run-up phase 31 and a warm-up phase 32 which partially overlap one another in time. No bearing diagnosis is carried out during the commissioning phase 31, 32. In the normal operating phase 33 after the commissioning phase 31, 32, the rotational speed 42 is more or less constant. Temperature changes in the commissioning phase 31, 32 are therefore not caused by rotational speed changes. Bearing diagnoses which produce plausible results can be carried out during the quasi-stationary condition of the normal operating phase 33. In the example, a substantial increase in the acoustic emission 41 and a slight to substantial increase in the temperature 42 are observed at the end 34 of the normal operating phase 33. Increasing bearing wear can be inferred from the simultaneous occurrence of the substantial increase in the acoustic emission 41 in conjunction with the tangible temperature increase. This can be used in the sensor element 10 to generate a warning signal (with a corresponding condition characteristic value) in a timely manner in order to initiate maintenance measures. The sensor element 10 is flexibly parameterizable in order to implement an adaptation of the evaluation method according to specific applications or monitoring objects 18 (such as, for example, pumps, bearings, gears, fans, compressor monitoring). The data 52, 53, 54, 55 to be fused with the acoustic emission signal 51, the respective fusion method and also evaluation rules and/or evaluation weightings are defined in each case for this purpose. Different application-specific methods of this type are described in detail below.

Example of cavitation detection in pumps: A fusion of acoustic emission detection and temperature detection is appropriate, since cavitation is strongly temperature-dependent. A synchronization with the pump rotational speed 45 is required for the localization of the cavitation source. To do this, an external rotational speed input 28, a network signal (e.g. of a PTP telegram) or an evaluation of a magnetic field sensor 14 of the sensor element 10 can be provided (PTP=Precision Time Protocol). The signal 53 of the vibration sensor 13 of the sensor element 10 represents an indicator of the severity of damage. If this additional signal 53 has a high intensity, a plausibility 46 of the acoustic emission signal 51 increases, justifying the initiation of a deactivation of the pump 18. This plausibility 46 (as a probability) can be used as additional information to a condition characteristic value of the pump 18.

Example of bearing diagnosis: Acoustic emission occurs in the high frequency range in bearings 18 during a run-up phase 31 due to a thermal expansion of machine components 18. Considered alone, this appears to reveal severe bearing damage. However, there is in fact no real damage signal, but rather material relaxation with expansion due to heating. An appropriate acoustic emission evaluation in order to assess the question of whether any bearing damage is present is possible only in the thermally stable condition. The detection and monitoring of the warm-up process by an additional temperature sensor 12 is appropriate in order to avoid too fast a run-up in the cold condition. An excessive heating results in a reduction in the bearing gap (bearing clearance) and in a ‘seizure’ of the bearing 18. A viscosity of the lubricant and the type of friction can be inferred through fusion of temperature measurement and acoustic emission measurement.

Example of bearing currents on engine bearings: Bearing currents similarly express themselves through acoustic emission 41. The acoustic emission 41 typically correlates with an engine vibration, since the discharge in the bearing 18 always occurs at particularly high vibration amplitudes (at which a bearing clearance constricts to a minimum). A magnetic field sensor 14 also can similarly supply signals during bearing current events. A classification of the type of the bearing currents is possible with the sensor element 10:
Acoustic emission 41 and temperature increase are an indication of ohmic bearing current or bearing current due to spark erosion.
Bearing current flashovers with spark erosion usually occur with low-frequency vibrations of the installation. The lubricant film thickness is modulated, and acoustic emission 41 and magnetic field pulses occur during bearing current events. The resulting damage (groove formation in the outer ring and later polygonization of the inner ring) can be detected with a low-frequency vibration sensor 13.

The progress of bearing current damage and of the condition of the monitoring object 18 can be tracked by joint evaluation of acoustic emission data 51, temperature data 52 and vibration data 53 (possibly magnetic field data 54 and rotational speed data 55 also, the latter e.g. by magnetic field measurement) in the evaluation device 22. Alternatively or additionally to the rotational speed data 55, data from an external bearing current monitoring 15, 16 can also be used in the joint evaluation as an external data signal 55.

The sensor element 10 preferably comprises a digital interface 24. It is advantageous if the interface 24 supports an interface standard for a wired or for a wireless data connection (for example an Ethernet standard such as Fast Ethernet Physical, a CAN standard, a WLAN standard and/or Bluetooth). It is also appropriate if an adaptation can be carried out according to the specific application via the digital interface 24 along with the communication with the condition monitoring infrastructure 26. Signals with or without a timestamp can be transmitted via the digital interface 24. A transmission of the signals with a timestamp enables a synchronization with other system elements. As a further possible additional benefit, a localization of signal sources can be carried out independently thereof by timestamping and a plurality of sensors (for example on a pump head) via an amplitude or transit time method.

It can be provided that characteristic values are transmitted or are internally stored in normal operation. The storage can be effected in a ring buffer. A further development can be provided that a histogram is produced with consolidation of the oldest values.

A detailed analysis can be provided if damage events occur. A ‘snapshot’ of the measurement data 51, 52, 53, 54, 55 captured at high resolution can be transmitted for this purpose. A data compression can be used here.

The sensor element 10 can differ from known sensor elements in one or more of the following features:
A fusion of the sensor system for acoustic emission with additional quantities is supported in a sensor component 10 (in an integrated sensor component), wherein the additional quantities are, for example, a vibration, a temperature 42 and/or a magnetic field.
The sensor system 10 has integrated adaptable algorithms for fusion of the measured quantities and for acquiring additional information (for example rotational speed information 45 from a magnetic field change).
A probability 46 of the occurrence of consolidated condition characteristic values is determined by a plausibility monitoring of monitored condition data 51, 52, 53, 54, 55 and one of a plurality of possible condition characteristic values is selected as the result and is made available via the interface 24 of the higher-order monitoring device 26 as sensor output of the sensor element 10.

The sensor element 10 can offer one or more of the following advantages compared with known sensor elements:
A simple adaptation of the sensor element 10 (of the integrated measurement system) to different measurement tasks is possible.
An integrated magnetic field sensor 14 enables rotational speed detection from the magnetic field, with no communication with the converter being required for this purpose.
The sensor element 10 is retrofittable at low cost, and its installation cost is low.
A plausibility check of acoustic emission signals 51 is possible through fusion with further measured quantities. The sensor element 10 is resilient to a misinterpretation of acoustic emission signals 51.
The data volume is reduced due to the local data fusion of different physical quantities 41, 42, 45 in the sensor element 10 (in the integrated sensor element).
The wiring requirement is reduced, as a result of which the reliability of the monitoring system 60 is also improved.
The system costs for integration and multiple use of subsystems (communication interface, microprocessor, etc.) are reduced.
The adaptability of the sensor element 10 reduces type and part diversity and enables high quantities.

The invention has been described in detail with particular reference to preferred embodiments thereof and examples, but it will be understood that variations and modifications can be effected within the spirit and scope of the invention covered by the claims which may include the phrase “at least one of A, B and C” as an alternative expression that means one or more of A, B and C may be used, contrary to the holding in Superguide v. DIRECTV, 69 USPQ2d 1865 (Fed. Cir. 2004).

1-10. (canceled)

11. A sensor element, comprising:
an acoustic emission sensor configured to measure acoustic emission; and
one or more second sensors, each of the one or more second sensors being configured to measure a quantity that is different from acoustic emission.

12. The sensor element as claimed in claim 11, wherein a first one of the one or more second sensors is one of a temperature sensor configured to measure a temperature level and/or a temperature gradient, a vibration sensor configured to measure a vibration characteristic, and a magnetic field sensor configured to measure a magnetic field strength and/or a magnetic field direction.

13. The sensor element as claimed in claim 12, wherein a second one of the one or more second sensors is one of a temperature sensor configured to measure a temperature level and/or a temperature gradient, a vibration sensor configured to measure a vibration characteristic, and a magnetic field sensor configured to measure a magnetic field strength and/or a magnetic field direction.

14. The sensor element as claimed in claim 11, further comprising an interface configured to receive an external sensor signal from an external sensor.

15. The sensor element as claimed in claim 11, further comprising a digital interface configured to communicate with an external monitoring infrastructure.

16. The sensor element as claimed in claim 14, further comprising an evaluation device configured to generate a consolidated and/or condensed sensor signal by processing an output sensor signal from the acoustic emission sensor and one or more of output sensor signals from the one or more second sensors and the external sensor signal.

17. The sensor element as claimed in claim 16, wherein the evaluation device is configured to load a program code and/or execute a program code.

18. The sensor element as claimed in claim 16, wherein the evaluation device is configured to carry out a correlation between the output sensor signal from the acoustic emission sensor and one of the one or more output sensor signals from the one or more second sensors and/or between two of the output sensor signals from the one or more second sensors.

19. The sensor element as claimed in claim 16, wherein the evaluation device is configured to carry out a correlation between the external sensor signal and one or more of the output sensor signal from the acoustic emission sensor and the output sensor signals from the one or more second sensors.

20. A monitoring system, comprising:
a higher-order monitoring device; and
a sensor element as claimed in claim 11 connected to the higher-order monitoring device.

21. The sensor element as claimed in claim 14, wherein the external sensor is a rotational speed sensor and the external sensor signal is a rotational speed signal.

22. The sensor element as claimed in claim 14, wherein the external sensor is a bearing current sensor and the external sensor signal is a bearing current signal.

23. A sensor element, comprising:
an acoustic emission sensor configured to generate first electrical signals based on a strength and/or direction of measured acoustic emission from a monitoring object; and
one or more second sensors, each of the one or more second sensors being configured to generate second electrical signals based on a measured physical characteristic from the monitoring object that is different from the measured acoustic emission.

24. A sensing method, comprising:
measuring acoustic emission from a monitoring object; and
measuring one or more physical quantities from the monitoring object that are different from the measured acoustic emission.
